(19) United States
(12) Patent Application Publication
(10) Pub. No.: US 2008/0163705 A1
(43) Pub. Date: Jul. 10, 2008

(54) Test chamber apparatus

(75) Inventors: Masaki Kuwashima, Kanagawa (JP); Nobuo Takeda, Kanagawa (JP); Masashi Tsuyama, Kanagawa (JP); Shigeto Nishiuchi, Kanagawa (JP)

Correspondence Address: TOWNSEND AND TOWNSEND AND CREW LLP, TWO EMBARCADERO CENTER, 8TH FLOOR, SAN FRANCISCO, CA, 94111, US

(73) Assignee: Hitachi Global storage Technologies Netherlands B.V., Amsterdam (NL)

(21) Appl. No.: 12/006,597

(22) Filed: Jan. 4, 2008

(30) Foreign Application Priority Data
Jan. 5, 2007 (JP) 2007-000585

(51) Int. Cl. G01R 1/04

(52) U.S. Cl. 73/865.6

(57) ABSTRACT

Embodiments of the present invention help to maintain the sealing capability of a depressurized space where a test subject device is placed in a test chamber apparatus, and to accurately control air pressure in the depressurized space. In one embodiment of the present invention, a depressurized space and a separate space are separated by a connection board. The connection board transmits signals between a test computer and an HDD. The connection board is fixed to an inner wall defining the depressurized space and the separate space. An opening is formed on the inner wall. The connection board which is larger than the opening covers the opening. To maintain the air sealing property in the depressurized space, the connection board is fixed to the inner wall via a gasket.

### CROSS-REFERENCES TO RELATED APPLICATIONS

The instant nonprovisional patent application claims priority to Japanese Patent Application No. 2007-000585 filed Jan. 5, 2007 and which is incorporated by reference in its entirety herein for all purposes.

### BACKGROUND OF THE INVENTION

Data storage devices using various kinds of media, such as optical disks and magnetic tape, have been known in the art. In particular, a hard disk drive (HDD) has been widely used as a storage device of a computer and has been a storage device for current computer systems. Moreover, the HDD has found widespread application such as a removable memory used in a moving image recording/reproducing apparatus, a car navigation system, a cellular phone, or a digital camera, as well as the computer system, due to its outstanding characteristics.

An HDD comprises a magnetic disk for storing data and a head slider for accessing the magnetic disk. The head slider comprises a head element portion for reading from and/or writing to the magnetic disk and a slider on which the head element portion is formed. The head slider flies over the magnetic disk with a certain gap. The HDD further comprises an actuator to move the head slider to a desired position on the magnetic disk. The actuator is driven by a voice coil motor (VCM) and pivots about a pivotal axis to move the head slider over the rotating magnetic disk in its radial direction. Thereby, the head element portion accesses a desired track formed on the magnetic disk to read and write data.

In designing and manufacturing steps of the HDD, the HDD is placed within a depressurized space and connected to a test computer so that operation tests, settings and adjustments of various parameters, and the like are performed. Since the fly-height of the head slider changes depending on air pressure, tests under depressurized conditions such as the expected use environments are required. The HDD and the test computer are set in a test chamber apparatus and the HDD is tested there. The test chamber apparatus has a space for enclosing the HDD and the temperature and the air pressure inside the space are adjustable.

In the test on the HDD under the depressurized conditions, an important point during the test on the HDD is a sealing capability for the inside space for enclosing the HDD. If the inside space is not properly sealed, the inside space cannot be maintained under a desired air pressure so that the tests on the HDD cannot be carried out properly. In addition, the inside space cannot be maintained at a desired temperature so that the tests on the HDD cannot be carried out properly. In conventional techniques, some approaches have been proposed in which a hole is prepared on the wall of the chamber for placing the HDD, a cable is penetrated through the hole before filling the hole with a resin material, and then the HDD inside the depressurized space and the test computer outside the depressurized space are connected; and both of the HDD and the test computer are placed inside the depressurized space to perform tests.

Japanese Patent Publication No. 6-66881 discloses a semiconductor test system in which a signal pin is formed on a wall of a hermetically-sealed space via an insulating substance to connect the inside and the outside of the sealed space electrically as an example of a method for connecting the devices inside and outside a space.

In the above-described method for passing a cable through a hole provided on the wall of the sealed space, air passing through the inside of the cable may impair the sealing capability of the sealed space. Besides, since the cable is fixed to the wall with a resin material, if the cable is broken or a different type of test on the HDD is performed, it cannot be replaced easily. The method to set both of the HDD and the test computer inside the above-described sealed space requires a larger volume of depressurized space so that it is difficult to control air pressure accurately and delicately within the space.

### BRIEF SUMMARY OF THE INVENTION

Embodiments of the present invention maintain the sealing capability of a depressurized space where a test subject device is placed in a test chamber apparatus, and accurately control air pressure in the depressurized space. According to the particular embodiment disclosed in FIG. 3, a depressurized space 202 and a space 204 are separated by a connection board 205. The connection board 205 transmits signals between a test computer 300a and an HDD 100a. The connection board 205 is fixed to an inner wall 208 defining the depressurized space 202 and the space 204. An opening 207 is formed on the inner wall 208. The connection board 205 which is larger than the opening 207 covers the opening 207. To maintain the air sealing property in the depressurized space 202, the connection board 205 is fixed to the inner wall 208 via a gasket 206.

### BRIEF DESCRIPTION OF THE DRAWINGS

FIG. 1 is a plan view schematically showing the inside configuration of the HDD as a test subject device according to one embodiment.

FIG. 2 is a perspective view schematically showing the entire configuration of the test chamber apparatus and a part of its inside space according to an embodiment.

FIG. 3 is a cross-sectional view schematically showing a state that the HDD as a test subject device and the test computer are installed in the test chamber apparatus according to one embodiment.

FIG. 4 is a perspective view schematically showing a state that the connection board is installed according to one embodiment as viewed from the depressurized space side.

FIG. 5 is a perspective view schematically showing a state that the connection board is installed and the adapter board is connected as viewed from the depressurized space side according to one embodiment.

### DETAILED DESCRIPTION OF THE INVENTION

Embodiments of the present invention relate to a test chamber apparatus, and in particular to a test chamber apparatus including a depressurized space for placing a test subject device.

A test chamber apparatus according to an aspect of embodiments of the present invention comprises a depressurized space in which a test subject device to be tested by a test device is placed, a board fixed as a part of a wall for defining the depressurized space, a terminal formed on a surface of the board exposed to the depressurized space for transmitting signals between the test device and the test subject device, and a terminal formed on an opposite surface to the surface exposed to the depressurized space for transmitting signals between the test device and the test subject device. This achieves to maintain the sealing capability in the depressurized space and to accurately control air pressure in the depressurized space.

The board may be detachably fixed to the wall for defining the depressurized space via a sealing member so as to cover an opening which is formed on the wall for defining the depressurized space and is smaller than the board. This achieves to maintain the sealing capability in the depressurized space more reliably.

The test chamber apparatus may further comprise an attachable and detachable inter-connection board which is connected to the terminal on the surface of the board exposed to the depressurized space via circuitry and has a connector connected to the test subject device physically and electrically. This allows replacement of the inter-connection board easily in accordance with the test subject device and to deal with various kinds of test subject devices. Similarly, the test chamber apparatus may further comprise a second attachable and detachable inter-connection board which is connected to the terminal on the opposite surface of the board via circuitry and has a connector connected to the test subject device physically and electrically.

The test chamber apparatus may further comprise a cable which is connected to the terminal on the surface of the board exposed to the depressurized space physically and electrically and is connected to the test subject device via circuitry. This achieves to suppress deterioration of the signal quality. Moreover, the cable is preferably connected to the board electrically and physically by soldering at an end of the cable and has a connector at the other end of the cable. This achieves to suppress deterioration of the signal quality and to replace the parts connected to the cable easily.

Or, the test chamber apparatus may further comprise an inter-connection board which is connected to the board via circuitry and is connected to the test subject device with a connector physically and electrically. Moreover, the cable may be connected to the inter-connection board electrically and physically with a connector and is connected to the board electrically and physically by soldering. This achieves to suppress deterioration of the signal quality.

According to embodiments of the present invention, in a test chamber apparatus, the sealing property of the depressurized space for setting the test subject device can be maintained so that accurate air pressure control for the depressurized space is achieved.

Hereinafter, a preferred embodiment of the present invention is described. For clearness of explanation, the following description and the accompanying drawings contain omissions and simplifications as appropriate. Throughout the drawings, the like components are denoted by like reference numerals, and their repetitive description is omitted if not necessary for the sake of clearness. A feature of the present embodiment is a configuration of a test chamber apparatus for enclosing a test subject device in a space and testing the test subject device under depressurized conditions. In the present embodiment, a hard disk drive (HDD) will be described by way of example of the test subject device. First, the configuration of the HDD which is tested in the test chamber apparatus according to the present embodiment will be described.

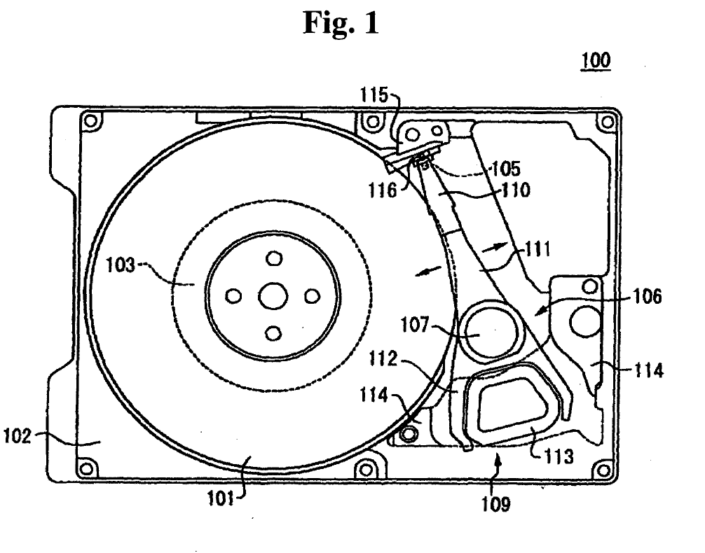

FIG. 1 is a plan view schematically showing a configuration of an HDD 100. The HDD 100 includes a magnetic disk 101 which is a recording disk for storing data. The magnetic disk 101 is a non-volatile memory to record data by a magnetic layer magnetized. Respective components of the HDD 100 are enclosed within a base 102. The base 102 is fixed via a cover (not shown) for covering a top opening of the base 102 and a gasket (not shown) to constitute a disk enclosure (housing) for enclosing the respective components of the HDD 100.

The head slider 105 comprises a head element portion for writing to and/or reading from the magnetic disk 101 with regard to data input from and/or output to a host (not shown) and a slider a surface on which the head element portion is formed. The head element portion includes a recording element for converting electric signals to magnetic fields in accordance with data to be stored on the magnetic disk 101 and/or a reproducing element for converting magnetic fields from the magnetic disk 101 to electric signals.

An actuator 106 supports and moves the head slider 105. The actuator 106 is supported pivotably by a pivotal axis 107 and is driven by a voice coil motor (VCM) 109 as a driving mechanism. The actuator 106 comprises respective components of a suspension 110, an arm 111, a coil support 112, and a flat coil 113 connected in order from the tip end of the head slider 105 in a longitudinal direction where the head slider is placed. The VCM 109 consists of a flat coil 113, a stator magnet (not shown) fixed to an upper stator magnet support plate 114, and a lower stator magnet (not shown).

The magnetic disk 101 is supported by a spindle motor (SPM) 103 fixed to the base 102 and is rotated by the SPM 103 at a predetermined rate. The actuator 106 moves the head slider 105 over a data region on the surface of the rotating magnetic disk 101 for reading/writing data from and to the magnetic disk 101. The pressure by air viscosity between the air bearing surface (ABS) of the slider facing the magnetic disk 101 and the rotating magnetic disk 101 balances to a pressure applied toward the magnetic disk 101 by the suspension 110. The head slider 105 flies over the magnetic disk 101 with a certain gap.

When the magnetic disk 101 stops rotating, for example, the actuator 106 retracts the head slider 105 from above the data region to a ramp 115. Embodiments of the present invention can be applied to a contact start and stop (CSS) scheme in which the head slider 105 is retracted to a zone provided in an inner periphery of the magnetic disk 101 when it does not write or read data. For the sake of simplicity, the above-described HDD is a type that the number of the magnetic disk 101 is one and the storage surface is one side, but the HDD 100 may be equipped with one or more magnetic disks with the both sides of storage surfaces.

In a typical manufacturing of the HDD 100, first, the head slider 105 is fabricated. Aside from the head slider 105, the suspension 110 is fabricated. The head slider 105 is fixed to the suspension 110 to fabricate a head gimbal assembly (HGA). Then, an arm 111 and a VCM coil are fixed to the HGA to fabricate a head stack assembly (HSA) which is an assembly of the actuator 106 and the head slider 105. In addition to the fabricated HSA, the SPM 103, the magnetic disk 101, and the like are mounted within the base 102 and the space inside the base 102 is sealed by a top cover so that a head disk assembly (HDA) is finished. A circuit board (not shown) on which a control circuit is implemented is mounted on this HDA, then assembly of the HDD 100 is finished.

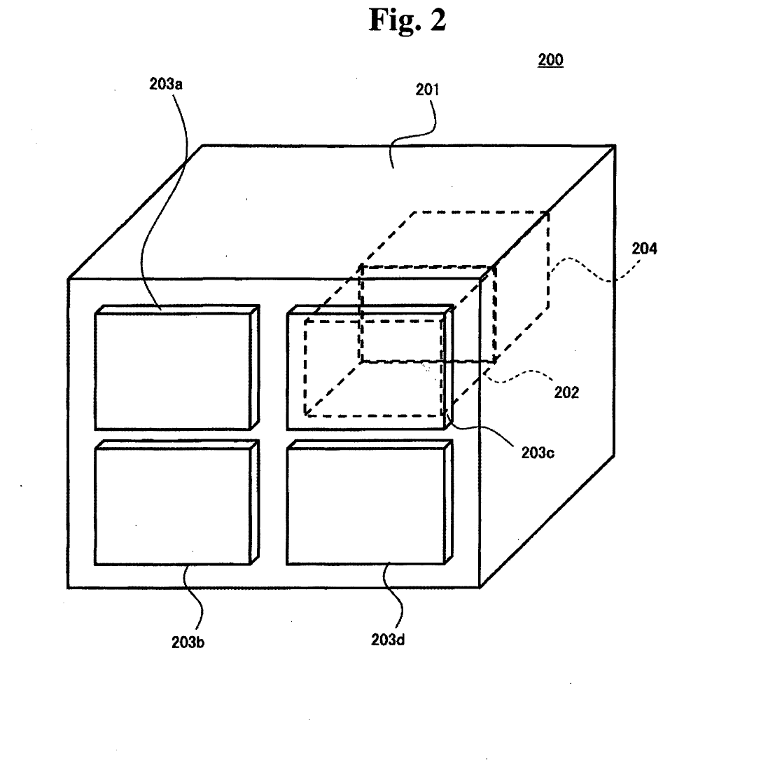

The HDD 100 assembled in this way is placed within a depressurized space in a sampling test in designing or manufacturing steps and is connected to a special test computer, and then performance tests before delivery are performed and various parameters are set or adjusted on the HDD. FIG. 2 is a perspective view schematically showing an appearance of a test chamber apparatus 200 according to the present embodiment and a part of the space formed inside the chamber.

In FIG. 2, a part of the test chamber apparatus 200 is shown transparently. As shown in FIG. 2, the test chamber apparatus 200 according to the present embodiment is enclosed with exterior walls 201 and a plurality of rooms are provided therein. One of them is a space 202 in which the HDD 1 as a test subject device is to be placed. Since the space 202 is maintained under depressurized conditions, it is referred to as a depressurized space 202 hereinbelow. The level of the air pressure changes depending on the design. An inlet of the depressurized space 202 is closed by an opening and closing door 203c. In the example of FIG. 2, four opening and closing doors 203a to 203d are illustrated.

A tester opens the opening and closing door 203c, places the HDD 100 inside the depressurized space 202, and maintains the depressurized space 202 under depressurized conditions with the opening and closing door 203c closed. At the back of the depressurized space 202 or the opposed side of the opening and closing door 203c, a space 204 which is a different room from the depressurized space 202 exists. The space 204 encloses a test computer as an example of a test device for performing tests on the HDD 100. Here, although FIG. 2 illustrates the depressurized space 202 and the space 204 corresponding to the opening and closing door 203c, the test chamber apparatus 200 of course comprises depressurized spaces 202 and spaces 204 corresponding to the other opening and closing doors 203a, 203b, and 203d, respectively.

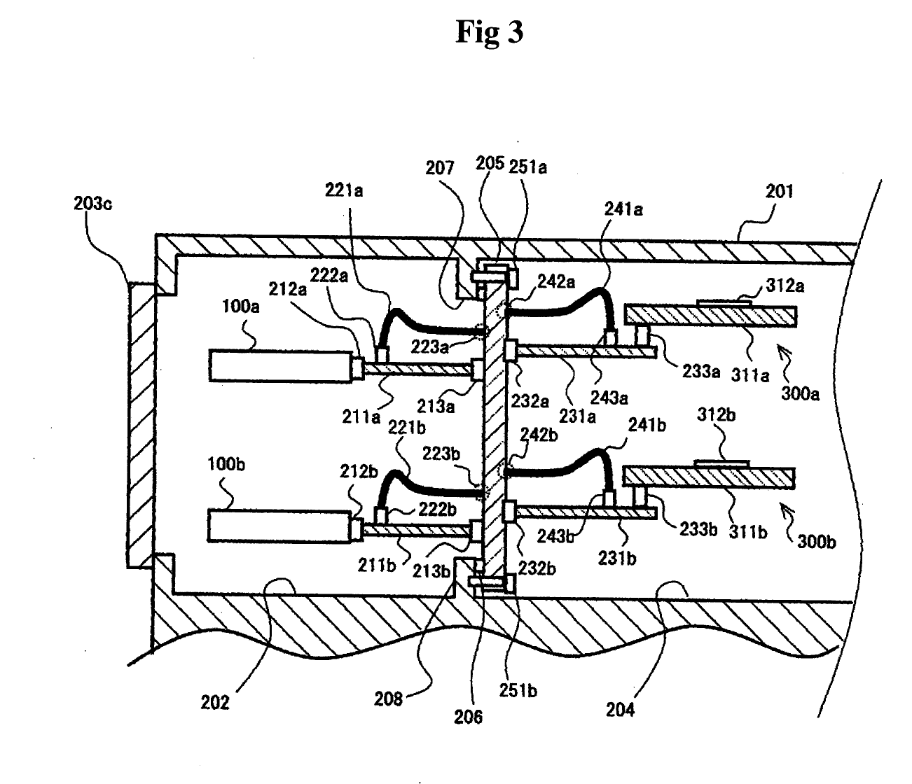

FIG. 3 is a cross-sectional view showing a state that HDDs 100a and 100b, test computers 300a and 300b are placed in the depressurized space 202 and the space 204, respectively. The depressurized space 202 is maintained under depressurized conditions by means of a pump (not shown). The opening and closing door 203c is closed to maintain the sealing capability of the depressurized space 202. In the example of FIG. 3, the depressurized space 202 encloses two HDDs 100a and 100b and the space 204 encloses two test computers 300a and 300b. The test computers 300a and 300b are connected to a host computer (not shown) outside the test chamber apparatus 200 and start tests on the HDDs 100a and 100b according to instructions from the host computer, and report the test results to the host computer. In FIG. 32, an example is shown in which the two HDDs are enclosed in the depressurized space 202, but it is not limited to two but a plurality of pairs can be enclosed, assuming that two HDDs are a pair.

The test computer 300a performs tests on the HDD 100a connected thereto via circuitry and the test computer 300b performs tests on the HDD 100b connected via circuitry. Connection via circuitry means being connected via wirings, terminals, or other circuits and being connected in a state in which signals on the circuit can be sent and received. The test computers 300a and 300b are equipped with ICs 312a and 312b, CPU boards 311a and 311b on which the ICs 312a and 312b are implemented, respectively. In addition, the test computers 300a and 300b are equipped with interface boards 231a and 231b to generate signals from and to the HDDs 100a and 100b, respectively. As shown in FIG. 3, the configuration and the connection configuration of the test computer 300a and the HDD 100a are the same as the ones of the test computer 300b and the HDD 100b. Therefore, descriptions of the test computer 300a and the HDD 100a will be made, while descriptions of the test computer 300b and the HDD 100b will be omitted hereinafter.

The depressurized space 202 and the space 204 are divided by a connection board 205. The connection board 205 comprises terminals, wirings, and connectors, and transmits signals between the test computer 300a and the HDD 100a in addition to power. The connection board 205 is fixed to an inner wall 208 which defines the depressurized space 202 and 204. On the inner wall 208, an opening 207 is formed. The connection board 205 which is larger than the opening 207 covers the whole opening 207. Therefore, the connection board 205 becomes a wall to define a part of the depressurized space 202. In order to maintain the air sealing property in the depressurized space 202, the connection board 205 is fixed to the inner wall 208 via a gasket 206.

Typically, the gasket 206 is a resin member such as of silicon rubber. The gasket 206 is sandwiched between the inner wall 208 and the connection board 205 and seals the depressurized space 202 as a sealing material. In the example of FIG. 3, the connection board 205 is placed within the space 204 and is fixed to the surface of the inner wall 208 on the space 204 side. However, it may be fixed to the surface on the depressurized space 202 side.

The connection board 205 is fixed to the inner wall 208 detachably with screws 251a and 251b. Attaching and detaching the screws allows replacement of the connection board 205 easily. The connection board 205 can be replaced corresponding to a different HDD 100, or can be replaced easily in case that the connection board 205 is broken, for example.

The HDD 100a is connected to the connection board 205 via an adapter board 211a as an inter-connection board. Therefore, the HDD 100a is connected to the adapter board 211a via circuitry, too. The HDD 100a is connected to the adapter board 211a physically and electrically via a connector 212a. Using the connector 212a enables to easily attach and detach the HDD 100a to and from the adapter board 211a. The connector 212a transmits data which is high-speed signals to be transmitted in the tests or low-speed signals which indicates that the HDD 100a is in operation, and the like, in addition to power.

The connector is usually consisted of two components, a male connector and a female connector, and one of them is fixed to one device to be connected and the other is fixed to the other device to be connected. In the present specification, a concept of the connector includes either one of the male connector and the female connector or an entire connector as an assembly constituted by both of them.

On the opposite side of the connector 212a, the adapter board 211a is connected to the connection board 205 via the connector 213a. The adapter board 211a is fixed to the surface of the connection board 205 exposed to the depressurized space 202 and is provided to stand vertically to the surface and to extend from the surface. In the present example, the connector 213a includes a terminal which is formed on the surface of the connection board 205 exposed to the depressurized space 202 and connects the adapter board 211a physically and electrically to the connection board 205. Therefore, the adapter board 211a is connected to the connection board 205 via circuitry, too.

The test chamber apparatus 200 according to the present embodiment comprises a cable 221a connecting the connection board 205 and the adapter board 211a. The cable 221a is connected to the surface of the connection board 205 exposed to the depressurized space 202, at a connection section 223a. At the connection section 223a, the cable 221a is connected to a terminal on the connection board 205 electrically and physically by soldering. Further, in order to secure the physical connection of the cable 221a to the connection board 205, the connection section 223a is fixed by a resin material such as epoxy.

The connection section 223a of the cable 221a and the other end thereof are connected to the adapter board 211a physically and electrically via the connector 222a. Thus, the adapter board 211a is connected to the cable 221a via the connector 222a and is connected to the connection board 205 via the connector 213. Thereby, the adapter board 211a can be replaced easily depending on the HDD 100 to be tested or a malfunction and the like can be dealt with easily.

The cable 221a transmits high-speed (high-frequency) signals between the interface board 231a and the HDD 100a. Specifically, it transmits input and output data to and from the HDD 100a. Using the cable 221a can suppress deterioration of the signal quality comparing to the transmission using the wirings on the board. The cable 221a is connected to the connection board 205 by soldering and no connector is used. Since a connector is likely to deteriorate the signal quality, the cable 221a which is unlikely to be required for replacement is solder-connected to the connection board 205 to suppress deterioration of the signal quality.

On the other hand, the wiring formed on the adapter board 211a transmits low-speed signals such as power and signals indicating that the HDD 100a is operating, which are different from the actual input/output data in reading/writing of the HDD 100a. Thereby, the cable 221a as a standardized product corresponding to the interface can be used. Since the above-described low-speed signals hardly deteriorate, no problems will occur.

The test computer 300a is connected to the connection board 205 via an interface board 231a as an inter-connection board. The CPU board 311a is connected to the interface board 231a physically and electrically by connector 233a. Therefore, the CPU board 311a is connected to the interface board 231a via circuitry, too. Using the connector 233a enables to easily attach and detach the CPU board 311a to and from the interface board 231a. The connector 233a transmits data which is high-speed signals to be transmitted in the tests or low-speed signals which indicate that the HDD 100a is in operation, and the like.

On the opposite side of the connector 233a, the interface board 231a is connected to the connection board 205 via the connector 232a. The interface board 231a is fixed to the surface of the connection board 205 exposed to the space 204 and is set substantially vertical to the surface and extends from the surface. In the present example, the connector 232a includes a terminal which is formed on the surface of the connection board 205 exposed to the space 204 and connects the interface board 231a physically and electrically to the connection board 205. Therefore, the interface board 231a is connected to the connection board 205 via circuitry, too.

The test chamber apparatus 200 according to the present embodiment comprises a cable 241a connecting the connection board 205 and the interface board 231a. The cable 241a is connected to the surface of the connection board 205 exposed to the opposite side of depressurized space 202 at a connection section 242a. At the connection section 242a, the cable 241a is connected to a terminal on the connection board 205 electrically and physically by soldering. Further, in order to secure the physical connection of the cable 241a to the connection board 205, the connection section 242a is fixed by a resin material such as epoxy.

The connection section 242a of the cable 241a and the opposite end thereof is connected to the interface board 231a physically and electrically via the connector 243a. Thus, the interface board 231a is connected to the cable 241a via the connector 243a and is connected to the connection board 205 via the connector 232a. Thereby, the interface board 231a can be replaced easily depending on the HDD 100a to be tested or a malfunction and the like can be dealt with easily.

The cable 241a transmits high-speed (high-frequency) signals between the interface board 231a and the HDD 100a. Specifically, it transmits input and output data to and from the HDD 100a. Using the cable 241a can suppress deterioration of the signal quality comparing to the transmission using the wirings on the board. The cable 241a is connected to the connection board 205 by soldering so that the deterioration of the signal quality due to the connector can be suppressed. On the other hand, the wiring from the connector 232a formed on the interface board 231a transmits low-speed signals which are different from the actual input/output data in reading/writing of the HDD 100a.

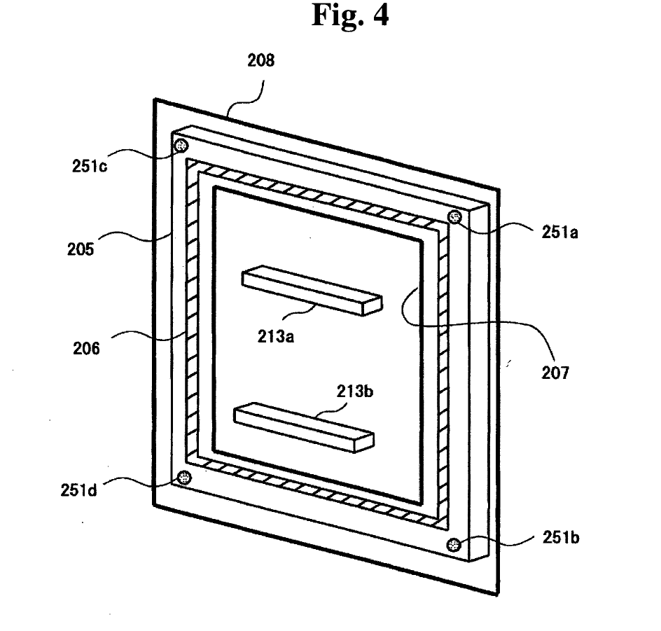

FIG. 4 is a perspective view schematically showing an installation state of the connection board 205 as viewed from the depressurized space 202 side. FIG. 4 shows the connection board 205 through the inner wall 208, which is shown transparently. FIG. 4 shows a state that the adapter boards 211a and 211b and the cables 221a and 221b are not connected to the connection board 205. The rectangular-shaped connection board 205 is fixed to the inner wall 208 with four screws 251a to 251d. The number of screws is decided in accordance with the design so as to securely fix the connection board 205. For example, only one screw or more than four six screws may fix the connection board 205. On the inner wall 208, a rectangular-shaped opening 207 is formed.

The area of the surface of the connection board 205 facing the inner wall 208 is larger than the opening 207 and the connection board 205 is placed to overlap the opening 207 completely and to cover the opening 207. Between the connection board 205 and the inner wall 208, a rectangular ring-shaped gasket 206 is provided. The size of the gasket 206 is larger than the one of the opening 207 and the gasket 206 surrounds the periphery of the opening 207. The gasket 206 is in a state of being pressed between the connection board 205 and the inner wall 208 and fills the gap between the connection board 205 and the inner wall 208 to prevent the air flowing from the space 204 to the depressurized space 202 through the opening 207. Outer shapes of the opening 207, the gasket 206, and the connection board 205 are appropriately selected in accordance with the designs. For example, the inner wall 208 may have an extending part between the connectors 213a and 213b and the part and the connection board 205 may be fixed with screws.

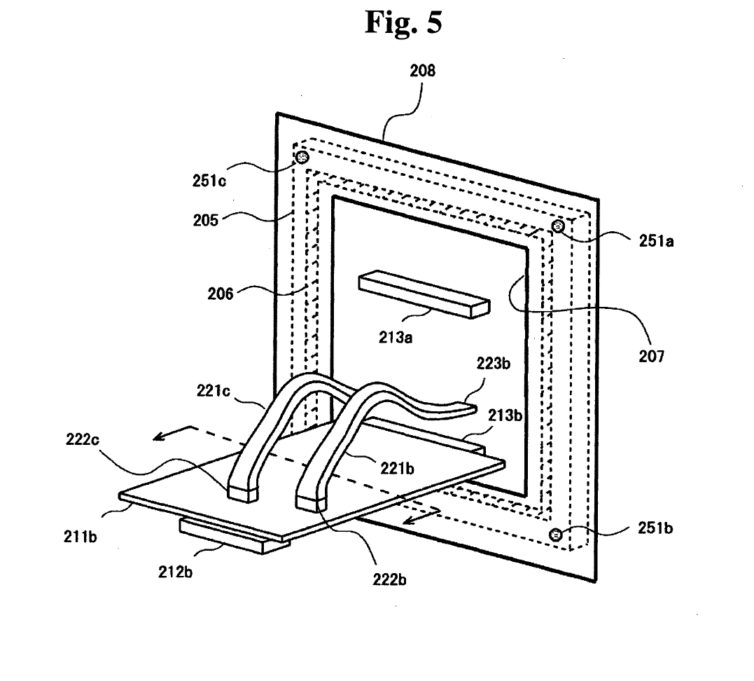

FIG. 5 schematically shows a state that the adapter board 211b 211a is connected to the connection board 205 shown in FIG. 4. Two cables 221b and 221c are provided to connect the connection board 205 and the adapter board 211b. The structures of the cables 221b and 221c are the same as the one of the above-described cable 221a. As an interface of the HDD 100, various types of protocols such as ATA and SCSI have been known and FIG. 5 illustrates an example of the SAS having two ports.

As described above, it is important to suppress the signal quality deterioration by means of signal transmission via the cables 221b and 221c. In order to achieve the object, the lengths of the wirings on the adapter board 211b for transmitting signals are preferably shorter. Therefore, the respective connectors 222b and 222c of the cables 221b and 221c are preferably close to the connector 212b for connecting the adapter board 211b and the HDD 100b.

Specifically, as shown by dotted lines and arrows in FIG. 5, in the direction from the end of the adapter board 211b on the connection board 205 side to the end on the connector 212b side, the cables 221b and 221c are preferably connected at the positions closer to the connector 212b than the center of the adapter board 211b. More preferably, the respective connectors 222b and 222c of the cables 221b and 221c are connected at the positions closer than the position at one third of the adapter board 211b from the end of the adapter board 211b on the connector 212b side in the above-described direction.

Even if only one of the two cables 221b and 221c is connected under the above-described conditions, certain effects can be expected, but it is preferred that both of the cables 221b and 221c are connected under the above-described conditions. With regard to the connection of the interface boards 231a and 231b and the cables 241a and 241b, the above-described conditions that the wirings on the boards become shorter are preferred to suppress the signal quality deterioration.

As set forth above, embodiments of the present invention are described by way of the certain embodiments but are not limited to the above embodiments. A person skilled in the art can easily modify, add, and convert the each element in the above embodiments within the scope of the present invention. For example, the test chamber apparatus according to embodiments of the present invention is especially useful for tests on HDDs under depressurized conditions, but it can be used for tests on other devices. In the above example, the adapter board and the interface board are directly connected to the connection board, but another interposer board may be inserted between the adapter board and the interface board and the connection board. In this case, the adapter board or the interface board is not directly connected to the connection board physically but is via circuitry. Also, connecting the cables to the respective interposer boards, the interposer board and the adapter board or the interposer board and the interface board may be connected with connectors.

What is claimed is:

1. A test chamber apparatus comprising:
a depressurized space in which a test subject device to be tested by a test device is placed;
a board fixed as a part of a wall for defining the depressurized space;
a terminal formed on a surface of the board exposed to the depressurized space for transmitting signals between the test device and the test subject device; and
a terminal formed on an opposite surface to the surface exposed to the depressurized space for transmitting signals between the test device and the test subject device.

2. The test chamber apparatus according to claim 1, wherein the board is detachably fixed to the wall for defining the depressurized space via a sealing member so as to cover an opening which is formed on the wall for defining the depressurized space and is smaller than the board.

3. The test chamber apparatus according to claim 1, further comprising an attachable and detachable inter-connection board which is connected to the terminal on the surface of the board exposed to the depressurized space via circuitry and has a connector connected to the test subject device physically and electrically.

4. The test chamber apparatus according to claim 3, further comprising a second attachable and detachable inter-connection board which is connected to the terminal on the opposite surface of the board via circuitry and has a connector connected to the test subject device physically and electrically.

5. The test chamber apparatus according to claim 1, further comprising a cable which is connected to the terminal on the surface of the board exposed to the depressurized space physically and electrically and is connected to the test subject device via circuitry.

6. The test chamber apparatus according to claim 5, wherein the cable is connected to the board electrically and physically by soldering at an end of the cable and has a connector at the other end of the cable.

7. The test chamber apparatus according to claim 5,
further comprising an inter-connection board which is connected to the board via circuitry and is connected to the test subject device with a connector physically and electrically; wherein
the cable is connected to the inter-connection board electrically and physically with a connector and is connected to the board electrically and physically by soldering.

8. The test chamber apparatus according to claim 7, wherein, on the inter-connection board, the connector of the cable is connected at a position closer to the connector to be connected electrically and physically to the test subject device than a center of the inter-connection board.
